(19) United States
(12) Patent Application Publication
(10) Pub. No.: US 2026/0255847 A1
(43) Pub. Date: Aug. 27, 2026

(54) COVER PLATE COMPONENT, METHOD FOR MANUFACTURING COVER PLATE COMPONENT, DISPLAY APPARATUS, AND BINDING METHOD FOR DISPLAY APPARATUS

(71) Applicant: wuhan Tianma Microelectronics Co., Ltd. Shanghai Branch, Shanghai (CN)

(72) Inventors: Lianzhen CHEN, Shanghai (CN); Mingyan HUANG, Shanghai (CN)

(73) Assignee: wuhan Tianma Microelectronics Co., Ltd. Shanghai Branch, Shanghai (CN)

(21) Appl. No.: 19/241,343

(22) Filed: Jun. 17, 2025

(30) Foreign Application Priority Data
Feb. 26, 2025 (CN) 202510220654.3

(51) Int. Cl. H10K 59/80

(52) U.S. Cl. CPC H10K 59/873

(57) ABSTRACT

The present application discloses a cover plate component, a method for manufacturing a cover plate component, a display apparatus, and a binding method for a display apparatus. The cover plate component includes a main body portion and a plating pattern portion, the main body portion includes a first area and a second area which at least partially surrounds the first area, and the main body portion includes a first surface and a second surface which are opposite to each other; and the plating pattern portion is provided on the first surface and is located in the second area.

### CROSS-REFERENCE TO RELATED APPLICATION

The present application claims priority to Chinese patent application No. 202510220654.3, entitled “COVER PLATE COMPONENT, METHOD FOR MANUFACTURING COVER PLATE COMPONENT, DISPLAY APPARATUS, AND BINDING METHOD FOR DISPLAY APPARATUS”, filed on February 26, 2025, the entire contents of which are incorporated here by reference.

### TECHNICAL FIELD

The present application relates to the technical field of electronic products, and in particular, to a cover plate component, a method for manufacturing a cover plate component, a display apparatus, and a binding method for a display apparatus.

### BACKGROUND

With the progress in science and technology, smart phones, tablet computers and other digital display devices are widely used, and display screens are indispensable interpersonal communication interfaces in these digital display devices. An organic light emitting diode (OLED) display apparatus has advantages of self-luminescence, energy-saving, consumption reduction, bendability, flexibility, and the like. The display apparatus does not need back light for displaying and has characteristics of a fast response and a desired display effect, so that it has attracted the attention of users, and is widely used in smart phones, tablet computers and other terminal products.

However, due to the structural limitation of the cover plate component of the existing display apparatus, the service performance of the cover plate component cannot meet the demand.

Therefore, there is an urgent need for a new cover plate component, a method for manufacturing a cover plate component, a display apparatus, and a binding method for the display apparatus.

### SUMMARY

Embodiments of the application provide a cover plate component, a method for manufacturing a cover plate component, a display apparatus, and a binding method for the display apparatus, in which the plating process is used to form a plating pattern portion so as to reduce the printing space and the level difference in thickness, and reduce the edge stack thickness while increasing the display area and reducing the bezel, which may reduce the binding bubbles in the adhesive layer when the first surface of the cover plate component is provided with the adhesive layer, thereby improving the service performance of the cover plate component.

In the first aspect, embodiments of the present application provides a cover plate component which includes:

a main body portion, which includes a first area and a second area which at least partially surrounds the first area, and which includes a first surface and a second surface which are opposite to each other; and a plating pattern portion, which is provided on the first surface and located in the second area.

In the second aspect, embodiments of the present application provide a method for manufacturing the cover plate component in any one of the above embodiments, and the method includes the following steps: providing a main body portion, the main body portion including a first area and a second area which at least partially surrounds the first area, and the main body portion including a first surface and a second surface which are opposite to each other; and forming a plating pattern portion on a first surface of the main body portion by a plating process, and forming the plating pattern portion in the second area.

In the third aspect, embodiments of the present application provide a display apparatus which includes: a display panel; and the cover plate component, which is located on a light emitting side of the display panel, the first surface of the main body portion of the cover plate component being located on a side of the second surface close to the display panel, wherein the cover plate component includes: a main body portion, which includes a first area and a second area which at least partially surrounds the first area, and which includes a first surface and a second surface which are opposite to each other; and a plating pattern portion, which is provided on the first surface and located in the second area.

In the fourth aspect, embodiments of the present application provide a binding method for a display apparatus which includes: providing a display panel; providing the cover plate component in any one of the above embodiments, the first surface of the main body portion of the cover plate component and the display panel being opposite to each other; and aligning and binding the cover plate component and the display panel by using the plating pattern portion of the cover plate component as reference benchmark.

### BRIEF DESCRIPTION OF THE DRAWINGS

In order to more clearly illustrate the technical solutions of the embodiments of the present application, the drawings to be used in the embodiments of the present application will be briefly introduced below. It is obvious that the drawings described below are merely some embodiments of the present application, and for those of ordinary skill in the art, other drawings can be obtained based on these drawings without inventive effort.

FIG. 1 is a schematic view of the second surface of a cover plate component according to embodiments of the present application;

FIG. 2 is a schematic view of a first surface of a cover plate component according to embodiments of the present application;

FIG. 3 is a schematic sectional view along B-B in FIG. 1 according to embodiments of the present application;

FIG. 4 is a partial enlarged view at C in FIG. 3 according to embodiments of the present application;

FIG. 5 is a flowchart of a method for manufacturing a cover plate component according to embodiments of the present application;

FIG. 6 is a schematic sectional view of a structure which is obtained in step S110 of the method for manufacturing a cover plate component according to embodiments of the present application;

FIG. 7 is a schematic structural view for illustrating a manufacturing process of the method for manufacturing a cover plate component according to embodiments of the present application;

FIG. 8 is a schematic view of a display apparatus according to embodiments of the present application;

FIG. 9 is a schematic sectional view of a display apparatus according to embodiments of the present application;

FIG. 10 is a schematic sectional view of a display apparatus according to other embodiments of the present application;

FIG. 11 is a flowchart of a binding method for the display apparatus according to embodiments of the present application; and

FIG. 12 is a schematic sectional view of a structure which is obtained in step S210 of a binding method for the display apparatus according to embodiments of the present application.

### DETAILED DESCRIPTION

Features and exemplary embodiments of various aspects of the present application will be described in detail below. Numerous specific details are set forth in the following detailed description to provide a thorough understanding of the present application. However, it will be apparent to a person skilled in the art that the present application may be practiced without some of these specific details. The following description of the embodiments is merely intended to provide a better understanding of the present application by illustrating examples of the present application.

It should be noted that, in the present application, the relational terms, such as first and second, are used merely to distinguish one entity or operation from another entity or operation, without necessarily requiring or implying any actual such relationships or orders for these entities or operations. Moreover, the terms “comprise”, “include”, or any other variants thereof, are intended to represent a non-exclusive inclusion, such that a process, method, article or device including a series of elements includes not only those elements, but also other elements that are not explicitly listed or elements inherent to such a process, method, article or device. Without more constraints, the elements following an expression “comprise/include…” do not exclude the existence of additional identical elements in the process, method, article or device that includes the elements.

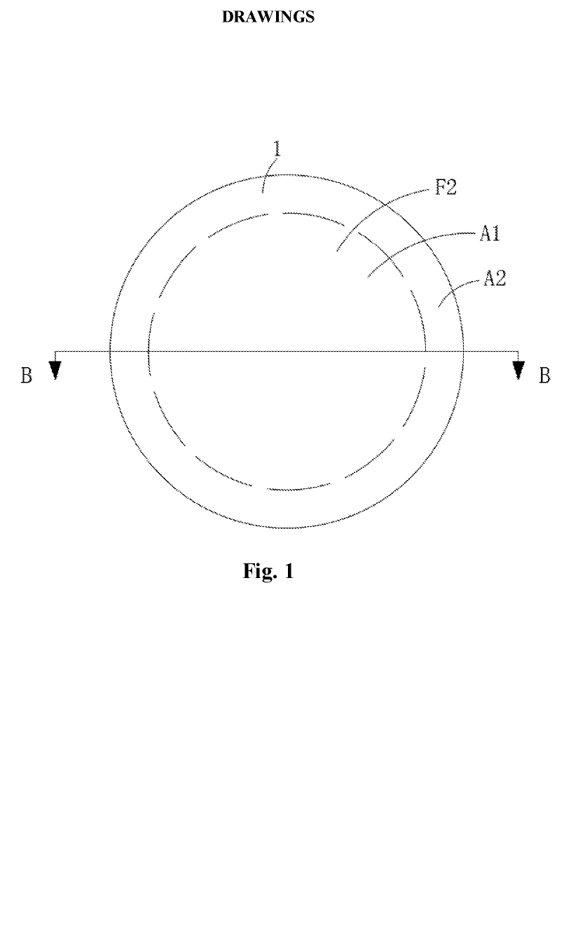

For a better understanding of the present application, a cover plate component, a method for manufacturing a cover plate component, a display apparatus, and a binding method for the display apparatus according to embodiments of the present application will be described in detail below with reference to FIG. 1 to FIG. 12.

In the related art, the screen printing process is often used for forming the ink layer at the edge of the cover plate to achieve the shielding of a part of traces or components, but the thickness and the width of the ink layer which is formed by using the screen printing process are relatively great, and the requirement for thinning or the narrow bezel cannot be met, affecting the service performance of the cover plate component.

In order to solve the above problem, using the plating process in the cover plate component according to the embodiments of the present application to form the plating pattern portion reduces the printing space and the level difference in thickness, reduces the edge stack thickness while increasing the display area and reducing the bezel, and may reduce the binding bubbles in the adhesive layer when the first surface of the cover plate component is provided with the adhesive layer, thereby improving the service performance of the cover plate component.

The embodiments of the present application provide the cover plate component 100 which includes the main body portion 1 and the plating pattern portion 2, the main body portion 1 includes the first area A1, and the second area A2 which at least partially surrounds the first area A1, and the main body portion 1 includes the first surface F1 and the second surface F2 which are opposite to each other, and the plating pattern portion 2 is provided on the first surface F1 and is located in the second area A2.

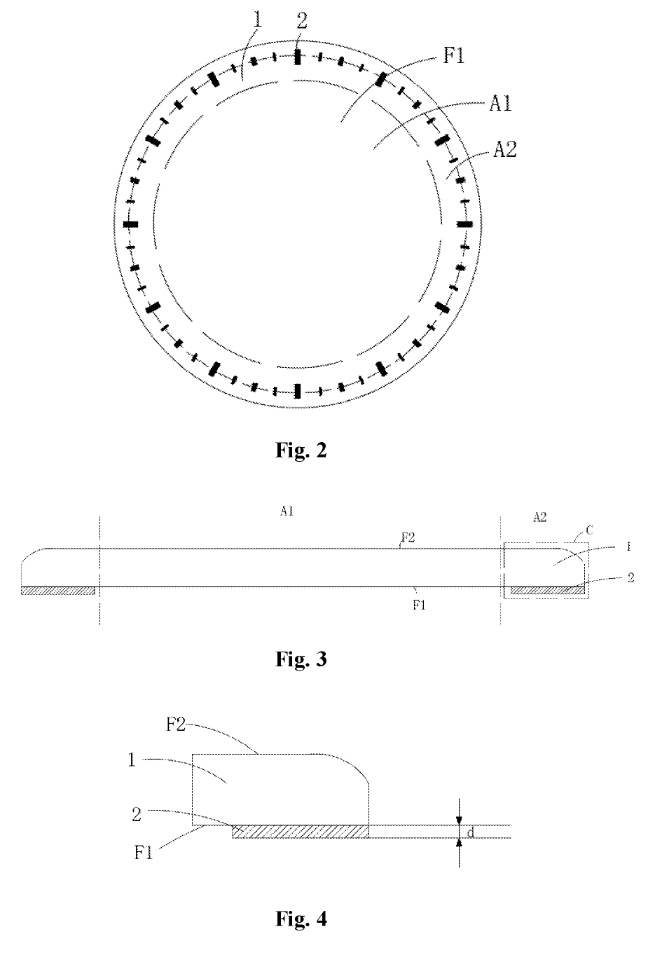

Referring to FIG. 1 to FIG. 3, FIG. 1 is a schematic view of the second surface F2 of the cover plate component 100 according to the embodiments of the present application; FIG. 2 is a schematic view of the first surface F1 of the cover plate component 100 according to the embodiments of the present application; and FIG. 3 is a schematic sectional view along B-B in FIG. 1 according to the embodiments of the present application.

The cover plate component 100 according to the embodiments of the present application includes the main body portion 1 and the plating pattern portion 2, and the plating pattern portion 2 is the part in which a required pattern is formed by using the plating process; compared with using the printing process such as the screen printing to form the component in the second area A2 in the related art, using the plating process to form the plating pattern portion 2 may reduce the printing space and the level difference in thickness, reduce the edge stack thickness while increasing the display area and reducing the bezel, and may reduce the binding bubbles in the adhesive layer 300 when the first surface F1 of the cover plate component 100 is provided with the adhesive layer 300, thereby improving the service performance of the cover plate component 100.

It may be understood that the main body portion 1 includes the first area A1 and the second area A2 which at least partially surrounds the first area A1, the first area A1 may be the central area of the main body portion 1, and the second area A2 may be the edge area of the main body portion 1; optionally, the second area A2 completely surrounds the first area A1.

When the cover plate component 100 is applied in the display panel 200, the first surface F1 may correspond to the light entrance surface (the surface which is close to the display panel 200) of the main body portion 1, and the second surface F2 may correspond to the light exit surface (the surface which is away from the display panel 200) of the main body portion 1.

It should be noted that the plating process refers to the technique for forming a layer of thin film on the surface of the substrate material; the thickness and other dimensions such as width of this layer of thin film may reach the nanometer level; under a condition that the bezel is reduced, the thinning of the plating pattern portion 2 may reduce the binding bubbles. The plating process may specifically include the chemical plating process and the physical plating process; the chemical plating process includes electroplating, chemical solution deposition, spin coating, chemical vapor deposition, plasma-enhanced chemical vapor deposition, and the like, and the physical plating process includes physical vapor deposition, thermal evaporation deposition, and the like; the plating pattern portion 2 in this embodiment may be manufactured by selecting a suitable plating process based on actual needs, which is not particularly limited.

The main body portion 1 may be made of a material with high light transmittance such as glass to serve the function of protecting the display panel 200. Specifically, the main body portion 1 may be made of a rigid material, with the cost being relatively low; or the main body portion 1 may be made of a flexible material, so that the main body portion 1 is foldable and thus applied in a flexible and foldable display apparatus, that is, specifically, the main body portion 1 may be made of a transparent, flexible and foldable material such as ultra thin glass (UTG), colorless polyimide (CPI), or polyethylene terephthalate (PET), so that the main body portion 1 may be bent and folded, facilitating the application of the main body portion 1 in the foldable display apparatus.

In some optional embodiments, the plating pattern portion 2 includes the first state and the second state, and the pattern of the plating pattern portion 2 in the first state is different from the pattern of the plating pattern portion 2 in the second state.

Specifically, the plating pattern portion 2 which is made of different materials may be selected, so that the plating pattern portion 2 displays different patterns in different states, for example, different temperatures, light sources, and viewing angles, thereby facilitating binding and alignment and optimizing the rotation degree.

Optionally, although the plating pattern portion 2 may display specific patterns in both of the first state and the second state, there is difference in shape, dimension, and the like between two patterns. Alternatively, the plating pattern portion 2 may display a pattern only in one of the first state and the second state, and a pattern which is displayed in the other state may be transparent, so as to increase the light transmittance of the cover plate component 100.

Optionally, the transparency of the plating pattern portion 2 in the first state is greater than the transparency of the plating pattern portion 2 in the second state, that is, the lower the transparency is, the clearer the pattern is, and the darker the color is, the better the recognizability is; the higher the transparency is, the lighter the color is, and when the transparency is equal to 100%, the plating pattern portion 2 is completely transparent and invisible to the user. The state of the plating pattern portion 2 may be specifically adjusted based on actual needs; for example, when the plating pattern portion 2 needs to be used in alignment, it is necessary to keep the plating pattern portion 2 in the visible state, such as the second state, and in the subsequent use process, if the plating pattern portion 2 is not needed, the plating pattern portion 2 may be in the first state.

In some optional embodiments, the plating pattern portion 2 is transparent in the first state and is in black or gray in the second state; or the plating pattern portion 2 is colored in the second state. It may be understood that the “colored” may be a color other than black or gray, such as red, blue, green, and the like.

The specific material used in the plating pattern portion 2 may be adjusted, so that the plating pattern portion 2 is in a color under a particular condition, that is, the plating pattern portion 2 may be in black or gray in the second state to achieve the light shielding effect, or the plating pattern portion 2 is in a color other than black or gray in the second state, but is transparent and is not in a color in the first state.

Optionally, the plating pattern portion 2 is at different temperatures, and/or exposed to different light sources, and/or under different viewing angles between the first state and the second state.

For example, the temperature in the first state may be greater than the temperature in the second state, and the material which is used for manufacturing the plating pattern portion 2 may be in different colors at different temperatures, so as to achieve that the pattern colors of the plating pattern portion 2 in the first state and the second state are different one another.

Alternatively, other materials are selected, so that the material of the plating pattern portion 2 display different patterns when irradiated with different light sources; for example, the plating pattern portion 2 may be irradiated with white light in the first state and may be irradiated with ultraviolet light or infrared light in the second state, which may be specifically selected based on actual needs and is not particularly limited.

In addition, suitable materials may be selected, so that the pattern colors of the plating pattern portion 2 under different viewing angles may be different one another to meet individual needs of customers.

In some optional embodiments, the material of the plating pattern portion 2 includes at least one of a photosensitive material or a temperature-sensitive material.

It may be understood that the photosensitive material specifically refers to a photosensitive color-changing material, the photosensitive color-changing material’s color can change under the irradiation of ultraviolet rays or sunlight and return to the original color without the irradiation of ultraviolet rays or sunlight, and thus be used as the material of the plating pattern portion 2; the light sources corresponding to the first state and the second state are different one another, so that the material of the plating pattern portion 2 displays different patterns under the irradiation of different light sources.

The temperature-sensitive material specifically refers to a temperature-sensitive color-changing material whose color can repeatedly change (from colored to colorless or from colorless to colored) based on the change in temperature, and the temperatures of the first state and the second state are different one another.

In some optional embodiments, the material of the plating pattern portion 2 includes a metal material, for example, at least one of metal materials such as aluminum and nickel; and as long as it is used in the plating pattern portion 2 for displaying different patterns in the first state and the second state, the material may be considered to be applied in the plating pattern portion 2.

Referring to FIG. 1 to FIG. 2, in some optional embodiments, along the direction which is perpendicular to the thickness direction of the cover plate component 100, the cross section of the main body portion 1 is a circle in shape; the first area A1 is a circle in shape, the second area A2 is a circular ring which surrounds the first area A1, and the plating pattern portion 2 is uniformly provided around the first area A1.

It may be understood that in this embodiment the cross section of the main body portion 1 is the circle in shape, that is, it may be applied in a display apparatus which is a circle in shape (such as a wearable device, a watch, and the like) or other display apparatuses which are required to be a circle in shape; the first area A1 is the circle in shape, and the second area A2 is the circular ring which surrounds the first area A1, that is, the second area A2 completely surrounds the first area A1, and the inner diameter of the second area A2 may be equal to the diameter of the first area A1, so that the first area A1 matches the second area A2.

Referring to FIG. 2, optionally, the plating pattern portion 2 is symmetrical with respect to the center of the first area A1, that is, the plating pattern portion 2 may be provided in a circle around the center of the first area A1 or may be provided only at some positions; as long as the plating pattern portion 2 is symmetrical with respect to the center of the first area A1, facilitating the alignment and binding of the plating pattern portion 2 and the display panel 200 to increase the accuracy of binding.

Referring to FIG. 2, in some optional embodiments, the orthographic projection of the plating pattern portion 2 on the main body portion 1 is at least one of a triangle, a rectangle, a circle, or a cross in shape. It should be noted that, in order to facilitate the manufacturing, the orthographic projection of the plating pattern portion 2 on the main body portion 1 may be only in one shape, such as any one of the triangle, the rectangle, the circle, and the cross; or in order to facilitate the grasping and the recognition of the plating pattern portion 2, the plating pattern portion 2 may be provided with many different shapes at the same time, for example, the orthographic projection of the plating pattern portion 2 on the main body portion 1 may be the rectangle and the circle in shape at the same time.

Of course, in addition to the regular shapes in the above example, based on actual needs, the orthographic projection of the plating pattern portion 2 on the main body portion 1 may be an irregular shape, and the irregular shape refers to those patterns which do not have a regular shape or boundary.

In some optional embodiments, the plating pattern portion 2 includes a plurality of scale marks which are provided at intervals along the outer edge of the main body portion 1.

The scale marks in this embodiment specifically refer to the marks which may be used for determining the rotation degree of the main body portion 1 or the relative position between the main body portion 1 and the display panel 200, and the specific shape and the dimension of the scale marks are not particularly limited and need to be selected based on actual requirements for a display apparatus; for example, when the scale marks are applied in a display apparatus, along the plane which is parallel to the main body portion 1, the width of the scale marks may be 1 nm to 100 nm, that is, the dimension of the scale marks such as the width and the thickness may reach the nanometer level to meet the requirements for the narrow bezel and the thinning.

In this embodiment, the plating pattern portion 2 present the scale marks at the edge of the main body portion 1 to avoid affecting the light emission effect of the first area A1.

Referring to FIG. 4, FIG. 4 is a partial enlarged view at C in FIG. 3 according to embodiments of the present application; optionally, the thickness d of the plating pattern portion 2 is greater than or equal to 5 nm and less than or equal to 25. For example, the thickness d of the plating pattern portion 2 may be equal to any one of 5 nm, 10 nm, 15 nm, 20 nm, and 25 nm, which is not particularly limited and may be selected based on actual needs.

In some optional embodiments, the plating pattern portion 2 includes the electroplating pattern portion, the electroplating pattern portion is a pattern portion which is formed by the electroplating process, and the electroplating process refers to a process for plating a thin layer of metal or alloy on the surface of a metal or other materials using the principle of electrolysis. In this embodiment, the electroplating pattern portion is formed on the first surface F1 of the second area A2 of the main body portion 1 by the electroplating process.

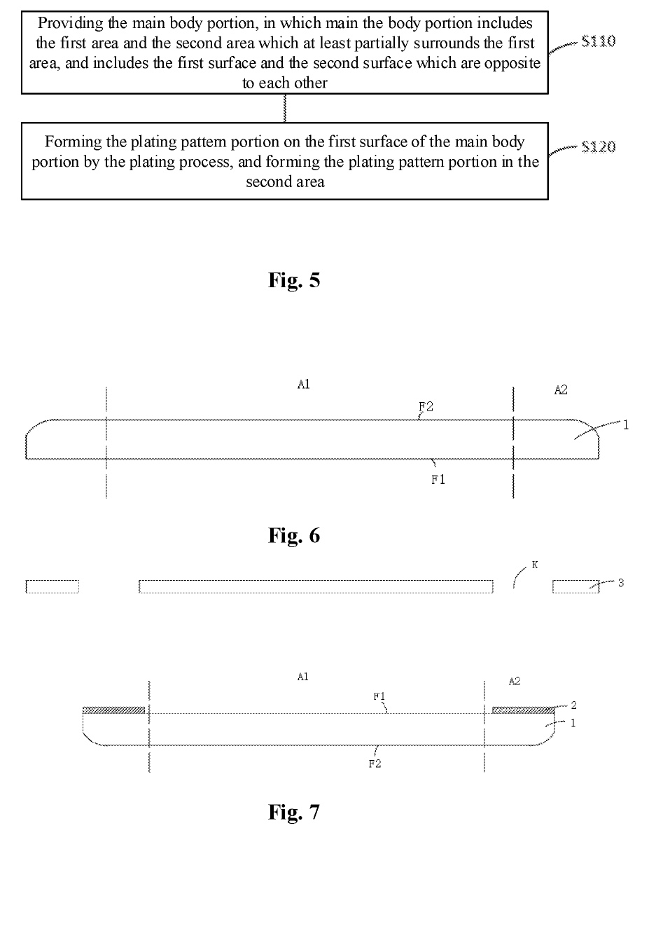

Referring to FIG. 5, FIG. 5 is a flowchart of a method for manufacturing a cover plate component according to embodiments of the present application; the embodiments of the present application further provide a method for manufacturing the cover plate component 100 in any one of the above embodiments, and the method includes the following steps:

S110: providing the main body portion 1, in which the main body portion 1 includes the first area A1 and the second area A2 which at least partially surrounds the first area A1, and the main body portion 1 includes the first surface F1 and the second surface F2 which are opposite to each other, as shown in FIG. 6;

S120: forming the plating pattern portion 2 on the first surface F1 of the main body portion 1 by the plating process, and forming the plating pattern portion 2 in the second area A2, as shown in FIG. 3.

The plating process is used in the method for manufacturing a cover plate component according to the embodiments of the present application to form the plating pattern portion 2, so as to reduce the printing space and the level difference in thickness, reduce the edge stack thickness while increasing the display area and reducing the bezel, and reduce the binding bubbles in the adhesive layer 300 when the first surface F1 of the cover plate component 100 is provided with the adhesive layer 300, thereby improving the service performance of the cover plate component 100.

In step S110, the main body portion 1 may be made of the material with high light transmittance such as glass to serve the function of protecting the display panel 200. Specifically, the main body portion 1 may be made of the rigid material, with the cost being relatively low; or the main body portion 1 may be made of the flexible material, so that the main body portion 1 is foldable and thus applied in the flexible and foldable display apparatus.

In step S120, the plating process refers to the technique for forming a layer of thin film on the surface of the substrate material; the thickness and other dimensions such as width of this layer of thin film may reach the nanometer level; and under a condition that the bezel is reduced, the thinning of the plating pattern portion 2 may reduce the binding bubbles.

The plating process may specifically include the chemical plating process and the physical plating process; the chemical plating process includes electroplating, chemical solution deposition, spin coating, chemical vapor deposition, plasma-enhanced chemical vapor deposition, and the like, and the physical plating process includes physical vapor deposition, thermal evaporation deposition, and the like; the plating pattern portion 2 in this embodiment may be manufactured by selecting a suitable plating process based on actual needs, which is not particularly limited.

In some optional embodiments, the step of forming the plating pattern portion 2 on the first surface F1 of the main body portion 1 by the plating process, and forming the plating pattern portion 2 in the second area A2 includes: forming the plating pattern portion 2 on the first surface F1 of the main body portion 1 by the electroplating process, and forming the plating pattern portion 2 in the second area A2.

The electroplating process refers to the process for plating a thin layer of metal or alloy on the surface of a metal or other materials using the principle of electrolysis. In this embodiment, the electroplating pattern portion is formed on the first surface F1 of the second area A2 of the main body portion 1 by the electroplating process.

The electroplating pattern portion is formed by the electroplating process, and the thickness and the width of the electroplating pattern portion may be controlled in the nanometer level to achieve the thinning and the narrow frame, thereby reducing the printing space and the level difference in thickness, reducing the edge stack thickness while increasing the display area and reducing the bezel, and reducing the binding bubbles in the adhesive layer 300 when the first surface F1 of the cover plate component 100 is provided with the adhesive layer 300.

Referring to FIG. 7, FIG. 7 is a schematic structural view for illustrating a manufacturing process of a method for manufacturing a cover plate component 100 according to embodiments of the present application; in some optional embodiments, the step of forming the plating pattern portion 2 on the first surface F1 of the main body portion 1 by the electroplating process and forming the plating pattern portion 2 in the second area A2 includes: providing the mask jig 3 which includes the patterned opening K; and with the masking of the mask jig 3, forming the plating pattern portion 2 on the first surface F1 of the main body portion 1 by allowing the material of the plating pattern portion 2 to pass through the opening K, so that the pattern of the plating pattern portion 2 corresponds to the pattern of the opening K.

In this embodiment, the material of the plating pattern portion 2 may specifically be a metal material such as aluminum and nickel; the plating pattern portion 2 may not be formed on a part of the first surface F1 which is masked by the mask jig 3 but may be formed on a part of the first surface F1 which corresponds to the opening K of the mask jig 3, that is, the pattern for adjusting the opening K of the mask jig 3 may be provided to form the desired pattern of the plating pattern portion 2.

It should be noted that the mask jig 3 may mask the clearance area which does not need to be plated, and the shape of the mask jig 3 may be adjusted according to the pattern of the plating pattern portion 2, that is, the shape that needs to be plated is exposed, and the remaining clearance area may be masked; for areas other than the area which needs to be plated, the accuracy may be adjusted based on the material of the jig, and the mask jig 3 may be made of a material such as a film, a steel jig, or a teflon jig, which is not particularly limited.

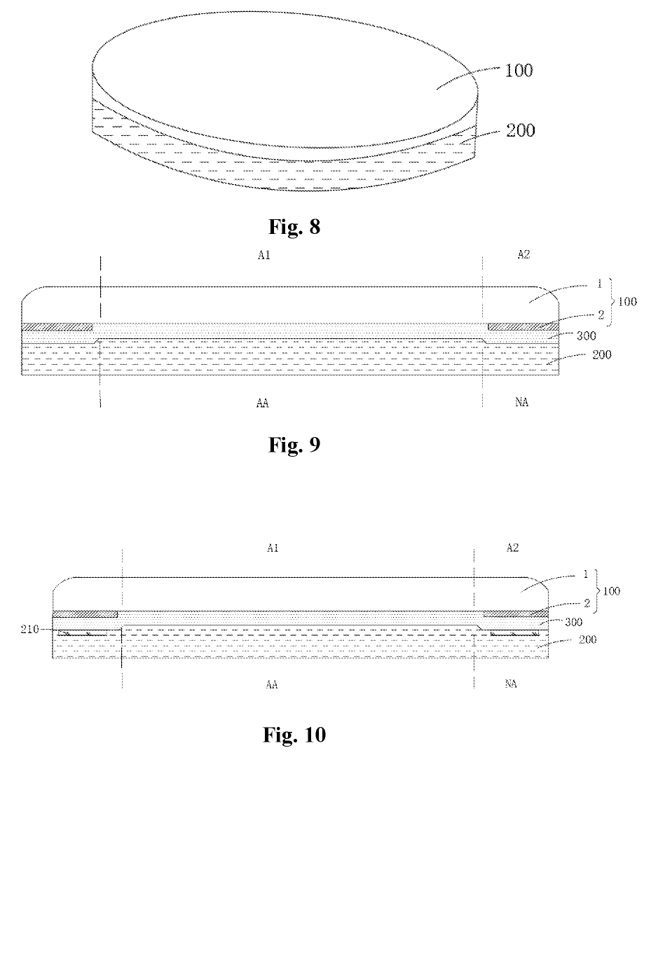

Referring to FIG. 8, FIG. 9 and, FIG. 10, FIG. 8 is a schematic view of a display apparatus according to embodiments of the present application; FIG. 9 is a schematic sectional view of a display apparatus according to embodiments of the present application; and FIG. 10 is a schematic sectional view of a display apparatus according to other embodiments of the present application; the embodiments of the present application further provide a display apparatus, the display apparatus includes the cover plate component 100 in any one of the above embodiments which is located on the light emitting side of the display panel 200, the first surface F1 of the main body portion 1 of the cover plate component 100 is located on a side of the second surface F2 close to the display panel 200; the first surface F1 of the main body portion 1 of the cover plate component 100 is located on a side of the second surface F2 close to the display panel 200, that is, the display panel 200 enters the main body portion 1 from the first surface F1 and exits from the second surface F2.

Referring to FIG. 9 or FIG. 10, optionally, the display panel 200 includes the display area and the non-display area which at least partially surrounds the display area; along the thickness direction of the display apparatus, the first area A1 of the main body portion 1 covers the display area, that is, the dimension of the first area A1 is greater than or equal to the dimension of the display area, so that emitting light of the display area can be emitted from the first area A1 without being affected by the plating pattern portion 2 of the second area A2.

Referring to FIG. 8, in some optional embodiments, the main body portion 1 and the display panel 200 both include the arc-shaped edges; along the thickness direction of the display apparatus, the main body portion 1 covers the display panel 200, that is, the main body portion 1 and the display panel 200 have the arc-edge structures (such as a circular structure, a double-arc-edge structure, or a four-arc-edge structure) correspondingly, so that the rotation degree error which is caused by inaccurate marking is solved by providing the plating pattern portion 2.

For example, the main body portion 1 and the display panel 200 both are a circle in shape.

Referring to FIG. 9 or FIG. 10, optionally, the display apparatus further includes the adhesive layer 300 which is located between the main body portion 1 and the display panel 200 and is in contact with the first surface F1 of the main body portion 1; along the thickness direction of the display apparatus, the orthographic projection of the adhesive layer 300 on the main body portion 1 overlaps the second area A2 of the main body portion 1, and at least a part of the adhesive layer 300 is located on a side of the plating pattern portion 2 away from the main body portion 1 and is bonded to the display panel 200.

Optionally, the film layers such as the encapsulation layer, the touch layer, and the polarizer may be sequentially stacked between the display panel and the adhesive layer 300, and the encapsulation layer may be provided closer to the display panel than the touch layer.

Optionally, the encapsulation layer is used for encapsulating and protecting the display panel; an inorganic material may specifically be made of a material such as silicon nitride, silicon oxide, and silicon oxynitride, and may specifically be formed by the chemical vapor deposition (CVD) process.

Optionally, the encapsulation layer includes the first encapsulation layer, and the material of the first encapsulation layer includes the inorganic material.

Optionally, the encapsulation layer further includes the second encapsulation layer which is located on a side of the first encapsulation layer away from the substrate, and the material of the second encapsulation layer includes an organic material. The organic material may be made of a resin or a polymer organic material and may specifically be formed by the inkjet printing (IJP) process.

Optionally, the encapsulation layer further includes the third encapsulation layer which is located on a side of the second encapsulation layer away from the substrate, the material of the third encapsulation layer includes the inorganic material, and continuously adding one inorganic encapsulation layer outside the organic encapsulation layer can further improve the encapsulation effect of the encapsulation layer; in this embodiment, the material of the third encapsulation layer may be the same as or different from the material of the first encapsulation layer, which is not particularly limited.

Optionally, the material of the first encapsulation layer is the same as the material of the third encapsulation layer, so that the first encapsulation layer and the third encapsulation layer may be manufactured by the same equipment, simplifying the process for manufacturing the display panel.

Optionally, the touch layer is used for achieving the touch function of the display apparatus and may be made of indium tin oxide (ITO) material. ITO has high light transmittance, which can effectively increase the light transmittance of the display panel and ensure the display effect. Of course, the touch layer may also be made of other materials, for example, metal materials such as molybdenum, titanium, aluminum, silver.

The polarizer may be used for increasing display contrast, reducing external light interference, improving viewing angles, and enhancing color performance. The polarizer is composed of a plurality of films which mainly include a polyvinyl alcohol (PVA) film, a tri-cellulose acetate (TAC) film, a protective film, a release film, and a pressure sensitive adhesive.

Of course, based on the specific type of and the requirements for the display apparatus, other film layers, such as a color film layer and a quantum dot layer, may be provided between the display panel 200 and the cover plate component 100, which is not particularly limited.

It may be understood that, in this embodiment, in addition to the corresponding position of the plating pattern portion 2, the adhesive layer 300 completely covers the first surface F1 of the main body portion 1, and in the second area A2, the adhesive layer 300 covers the plating pattern portion 2 and is in contact with a part of the first surface F1 which is exposed by the plating pattern portion 2, ensuring the adhesive effect.

Since the plating pattern portion 2 which is formed by the plating process has the smaller thickness d, the bubbles which are generated when the adhesive layer 300 is bonded can be effectively reduced, increasing the using effect of the display apparatus.

The adhesive layer 300 may be made of the optically clear adhesive (OCA). The OCA is a substrate-free double-faced binding adhesive tape which is obtained by the following step: making the optical acrylic glue into a substrate material, and then attaching a layer of release thin film to each of the upper surface and the lower surface. The OCA layer has uniform thickness and high flatness, high adhesive force, and high binding strength after binding. Of course, the adhesive layer 300 may be a layer which is made of other materials such as the double-faced adhesive.

Referring to FIG. 10, in some optional embodiments, the display panel 200 includes the alignment portion 210 which corresponds to the plating pattern portion 2, and the alignment portion 210 may be provided in the non-display area to facilitate the alignment with the plating pattern portion 2 and achieve the accurate binding between the display panel 200 and the cover plate component 100; of course, the alignment portion 210 may be provided in the display area of the display panel 200 as long as the normal display of the display area is not affected, which is not particularly limited.

The pattern of the alignment portion 210 may be selected based on the corresponding plating pattern portion 2 as long as it is convenient for the alignment between the alignment portion 210 and the plating pattern portion 2.

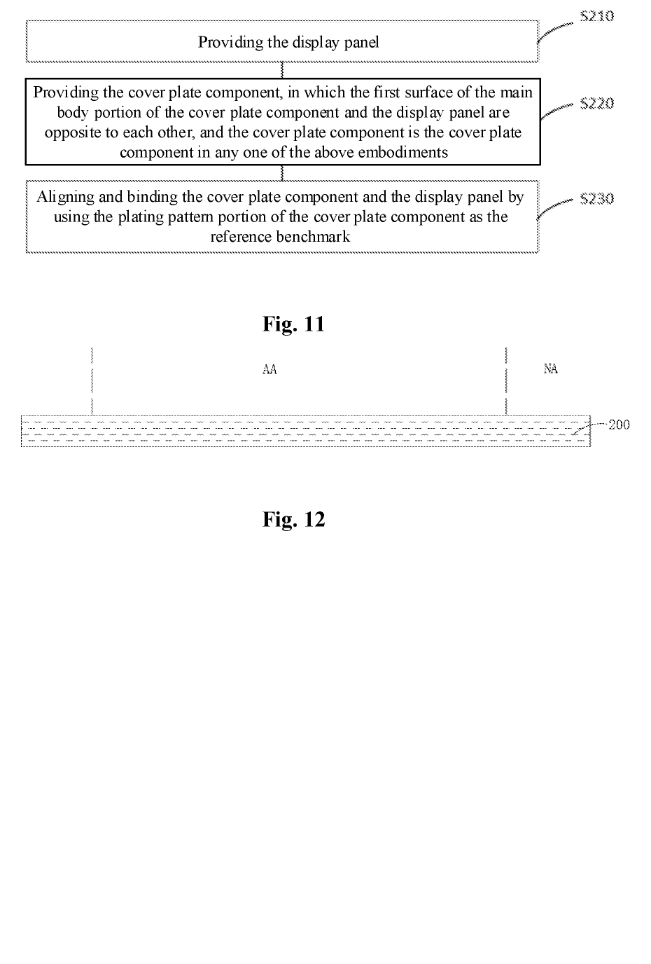

Referring to FIG. 11, FIG. 11 is a flowchart of a binding method for a display apparatus according to embodiments of the present application; the embodiments of the application further provides a binding method for a display apparatus, the method includes:

S210: providing the display panel 200, as shown in FIG. 12;

S220: providing the cover plate component 100 in any one of the above embodiments, in which the first surface F1 of the main body portion 1 of the cover plate component 100 and the display panel 200 are opposite to each other, as shown in FIG. 3;

S230: aligning and binding the cover plate component 100 and the display panel 200 by using the plating pattern portion 2 of the cover plate component 100 as the reference benchmark, as shown in FIG. 10.

In the binding method for a display apparatus according to the embodiments of the present application, the cover plate component 100 and the display panel 200 are aligned and bonded by using the plating pattern portion 2 of the cover plate component 100 as the reference benchmark, and the characteristics of the plating pattern portion 2, such as the thin film layer and the small width, are used for increasing the binding accuracy and the binding yield.

In step S 210, the display panel 200 may be the organic light emitting diode (OLED) display panel 200, the quantum dot light emitting diode (QLED) display panel 200, the micro-OLED display panel 200, or the like.

In step S220, the first surface F1 of the main body portion 1 of the cover plate component 100 and the display panel 200 are opposite to each other to facilitate subsequent alignment and binding.

In step S230, the plating pattern portion 2 includes the plurality of scale marks which are provided at intervals along the outer edge of the main body portion 1, the display panel 200 includes the alignment portion 210, and the cover plate component 100 and the display panel 200 are aligned and bonded by using the alignment portion 210 and the scale marks as the reference benchmark.

When binding is carried out, the relative positions of the alignment portion 210 and the scale marks may be aligned to achieve the highly accurate binding of the cover plate component 100 and the display panel 200, increasing the binding accuracy and the binding yield.

The display apparatus according to the embodiments of the present application has the technical effects of the technical solutions of the cover plate component 100 in any one of the above embodiments, and the explanations of structures and terms which are the same as or correspond to the above embodiments are not repeated here.

The display apparatus according to the embodiments of the present application may be any electronic product with the display function, including, but not limited to, the following categories: mobile phones, televisions, notebook computers, desktop displays, tablet computers, digital cameras, smart bracelets, smart glasses, vehicle-mounted displays, medical equipment, industrial control equipment, touch interactive terminals, and the like, which are not specifically limited in the embodiments of the present application.

The above are only specific embodiments of the present application, those skilled in the art may clearly understand that the specific operation processes of the above systems, modules and units may be referred to the processes in the foregoing method embodiments, which is not repeated here for the convenience and brevity of the description. It should be understood that the protection scope of the present application is not limited to this, and any person skilled in the art can easily think of various equivalent modifications or replacements within the technical scope disclosed in the present application, and these modifications or replacements should all be covered within the scope of protection of the present application.

It should also be noted that, the exemplary embodiments mentioned in the present application describe methods or systems based on a series of steps or apparatus. However, the present application is not limited to the above order of the steps. That is, the steps may be executed in the order described in the embodiments or in orders different from that in the embodiments, or several steps may be executed simultaneously.

What is claimed is:

1. A cover plate component, comprising:
a main body portion, which comprises a first area and a second area which at least partially surrounds the first area, and which comprises a first surface and a second surface which are opposite to each other; and
a plating pattern portion, which is provided on the first surface and located in the second area.

2. The cover plate component according to claim 1, wherein the plating pattern portion comprises a first state and a second state, and a pattern of the plating pattern portion in the first state is different from a pattern of the plating pattern portion in the second state.

3. The cover plate component according to claim 2, wherein transparency of the plating pattern portion in the first state is greater than transparency of the plating pattern portion in the second state.

4. The cover plate component according to claim 2, wherein the plating pattern portion is transparent in the first state and is in black or gray in the second state, or the plating pattern portion is colored in the second state.

5. The cover plate component according to claim 2, wherein the plating pattern portion is at different temperatures, and/or exposed to different light sources, and/or under different viewing angles between the first state and the second state.

6. The cover plate component according to claim 1, wherein a material of the plating pattern portion comprises at least one of a photosensitive material or a temperature sensitive material.

7. The cover plate component according to claim 1, wherein a material of the plating pattern portion comprises a metal material.

8. The cover plate component according to claim 1, wherein along a direction which is perpendicular to a thickness direction of the cover plate component, a cross section of the main body portion is a circle in shape; and
the first area is a circle in shape, the second area is a circular ring which surrounds the first area, and the plating pattern portion is uniformly provided around the first area.

9. The cover plate component according to claim 1, wherein the plating pattern portion is symmetrical with respect to a center of the first area.

10. The cover plate component according to claim 1, wherein an orthographic projection of the plating pattern portion on the main body portion is at least one of a triangle, a rectangle, a circle, or a cross in shape.

11. The cover plate component according to claim 10, wherein the plating pattern portion comprises a plurality of scale marks which are provided at intervals along an outer edge of the main body portion.

12. The cover plate component according to claim 1, wherein a thickness of the plating pattern portion is greater than or equal to 5 nm and less than or equal to 25 nm.

13. The cover plate component according to claim 10, wherein the plating pattern portion comprises an electroplating pattern portion.

14. A method for manufacturing the cover plate component, comprising following steps:
providing a main body portion, the main body portion comprising a first area and a second area which at least partially surrounds the first area, and the main body portion comprising a first surface and a second surface which are opposite to each other; and
forming a plating pattern portion on the first surface of the main body portion by a plating process, and forming the plating pattern portion in the second area.

15. The method for manufacturing the cover plate component according to claim 14, wherein the forming a plating pattern portion on the first surface of the main body portion by a plating process, and forming the plating pattern portion in the second area comprises:
forming a plating pattern portion on a first surface of the main body portion by an electroplating process, and forming the plating pattern portion in the second area.

16. The method for manufacturing the cover plate component according to claim 14, wherein the forming a plating pattern portion on the first surface of the main body portion by an electroplating process, and forming the plating pattern portion in the second area comprises:
providing a mask jig which comprises a patterned opening; and
with masking of the mask jig, forming the plating pattern portion on the first surface of the main body portion by allowing a material of the plating pattern portion to pass through the opening, so that a pattern of the plating pattern portion corresponds to a pattern of the opening.

17. A display apparatus comprising:
a display panel; and
the cover plate component, which is located on a light emitting side of the display panel, the first surface of the main body portion of the cover plate component being located on a side of the second surface close to the display panel,
wherein the cover plate component comprises:
a main body portion, which comprises a first area and a second area which at least partially surrounds the first area, and which comprises a first surface and a second surface which are opposite to each other; and
a plating pattern portion, which is provided on the first surface and located in the second area.

18. The display apparatus according to claim 17, wherein the display panel comprises a display area and a non-display area which at least partially surrounds the display area; and
along a thickness direction of the display apparatus, the first area of the main body portion covers the display area.

19. The display apparatus according to claim 17, wherein the main body portion and the display panel both comprise arc-shaped edges, and along a thickness direction of the display apparatus, the main body portion covers the display panel.

20. The display apparatus according to claim 17, further comprising an adhesive layer which is located between the main body portion and the display panel and in contact with the first surface of the main body portion; and
along a thickness direction of the display apparatus, an orthographic projection of the adhesive layer on the main body portion overlaps the second area of the main body portion, and at least a part of the adhesive layer is located on a side of the plating pattern portion away from the main body portion and is bonded to the display panel.
